(19) United States
(12) Patent Application Publication
(10) Pub. No.: US 2024/0372328 A1
(43) Pub. Date: Nov. 7, 2024

(54) Techniques for Providing Electrostatic Discharge (ESD) Protection to Resonant Cavity Mesas

(71) Applicant: Apple Inc., Cupertino, CA (US)

(72) Inventors: Siddharth Joshi, Saint-Egreve (FR); Nicolas Hotellier, Champagnier (FR); Fei Tan, Sunnyvale, CA (US); Anne-Laure Bavencove, La Sure en Chartreuse (FR); Chin-Han Lin, Santa Clara, CA (US); Arnaud Laflaquiere, Paris (FR)

(21) Appl. No.: 18/143,869

(22) Filed: May 5, 2023

(51) Int. Cl. H01S 5/183; H01L 27/02

(52) U.S. Cl. CPC H01S 5/18344; H01L 27/0248

(57) ABSTRACT

An optoelectronic device includes a silicon interposer and an array of resonant cavity mesas. The array of resonant cavity mesas is monolithically integrated in a set of one or more epitaxial layers and flip-chip bonded to the silicon interposer. The array of resonant cavity mesas includes a first subset of resonant cavity mesas connected to a first subset of conductors of the silicon interposer and biased to a first electrical polarity, and a second subset of resonant cavity mesas connected to a second subset of conductors of the silicon interposer. The second subset of resonant cavity mesas provides electrostatic discharge (ESD) protection for the first subset of resonant cavity mesas.

### TECHNICAL FIELD

Embodiments described herein relate to techniques for providing electrostatic discharge (ESD) protection for an optoelectronic device and, in particular, to providing ESD protection for resonant cavity mesas of the optoelectronic device.

### BACKGROUND

Consumer electronic devices may include a display and one or more user-facing sensors such as a front-facing camera, proximity sensor, ambient light sensor, fingerprint reader, depth-sensing camera, or the like. Some of such user-facing sensors may include resonant cavity mesas, which may be operable as vertical cavity surface-emitting laser (VCSEL) diodes. Depending on the design of a particular device in which these VCSEL diodes are used, the VCSEL diodes may be susceptible to ESD damage at different threshold voltages. Further, susceptibility of the VCSEL diodes to ESD damage can vary in accordance with an aperture size used for the VCSEL diodes, such that at a very low aperture size the VCSEL diodes may be damaged at an ESD voltage level ranging from 40 to 50 volt (V). Accordingly, solutions are needed to protect VCSEL diodes from ESD damage.

### SUMMARY

Embodiments described herein relate to an optoelectronic device. In a first embodiment, an optoelectronic device including a silicon interposer and an array of resonant cavity mesas is disclosed. The array of resonant cavity mesas may be monolithically integrated in a set of one or more epitaxial layers and flip-chip bonded to the silicon interposer. The array of resonant cavity mesas may include a first subset of resonant cavity mesas connected to a first subset of conductors of the silicon interposer and biased to a first electrical polarity, and a second subset of resonant cavity mesas connected to a second subset of conductors of the silicon interposer. The second subset of resonant cavity mesas may be configured to provide electrostatic discharge (ESD) protection for the first subset of resonant cavity mesas.

In the first embodiment, the first subset of resonant cavity mesas may be forward biased and operable as a set of VCSEL diodes, and the second subset of resonant cavity mesas may be reverse biased. Alternatively, the first subset of resonant cavity mesas may be reverse biased and operable as a set of resonant cavity photodetectors (RCPDs), and the second subset of resonant cavity mesas may be forward biased.

In the first embodiment, the silicon interposer may have n metal layers, and n may be greater than two. The first subset of conductors of the silicon interposer may be disposed in a first metal layer that is different from a second metal layer in which the second subset of conductors of the silicon interposer is disposed.

In the first embodiment, a ratio of a first number of resonant cavity mesas of the first subset of resonant cavity mesas to a second number of resonant cavity mesas of the second subset of resonant cavity mesas may be other than 1:1. The optoelectronic device may also include a third set of mesa structures which is configured to provide mechanical or structural support to the first and second subsets of resonant cavity mesas of the array of resonant cavity mesas.

In a second embodiment, an optoelectronic device including an array of resonant cavity mesas formed on a common substrate is disclosed. The array of resonant cavity mesas may include a first subset of resonant cavity mesas and a second subset of resonant cavity mesas. A first two or more resonant cavity mesas of the first subset of resonant cavity mesas may be electrically biased to a first polarity and may be operable as VCSEL diodes. Another (or a second) two or more resonant cavity mesas of the second subset of resonant cavity mesas may be electrically biased to a second polarity and may provide electrostatic discharge (ESD) protection for the first two or more resonant cavity mesas. The optoelectronic device may also include at least one trench in the common substrate. The at least one trench may electrically isolate the first subset of resonant cavity mesas from the second subset of resonant cavity mesas.

In the second embodiment, the optoelectronic device may also include a silicon interposer, which is disposed between the common substrate and the array of resonant cavity mesas. The first two or more resonant cavity mesas of the first subset of resonant cavity mesas may be electrically biased to the first polarity using a first subset of conductors disposed in the silicon interposer, and the second two or more resonant cavity mesas of the second subset of resonant cavity mesas may be electrically biased to the second polarity using a second subset of conductors disposed in the silicon interposer. The first subset of conductors may be disposed in a metal layer of the silicon interposer that is different from a metal layer of the silicon interposed in which the second subset of conductors is disposed.

In the second embodiment, the first subset of resonant cavity mesas and the second subset of resonant cavity mesas may form a set of forward biased diodes and a set of reverse biased diodes, respectively, connected in parallel for providing a bidirectional transient voltage suppressor (TVS). A ratio of a number of resonant cavity mesas of the first subset of resonant cavity mesas to a number of resonant cavity mesas of the second subset of resonant cavity mesas may be n:1, where n is equal to or not equal to 1. Alternatively, a ratio of a number of resonant cavity mesas of the first subset of resonant cavity mesas to a number of resonant cavity mesas of the second subset of resonant cavity mesas may be 1:n, where n is equal to or not equal to 1.

In a third embodiment, a method of making an optoelectronic device is disclosed. The method may include forming an array of resonant cavity mesas monolithically integrated in a set of one or more epitaxial layers on a substrate, and forming a silicon interposer circuit including a set of metal layers and a set of vias. The method may also include bonding the array of resonant cavity mesas to the silicon interposer circuit. The bonding may include connecting a first subset of resonant cavity mesas of the array of resonant cavity mesas to at least one of the metal layers or to a first subset of vias of the set of vias, and biasing the first subset of resonant cavity mesas to a first electrical polarity. The bonding may further include connecting a second subset of resonant cavity mesas of the array of resonant cavity mesas to at least one of the metal layers or to a second subset of vias of the set of vias, and biasing the second subset of resonant cavity mesas to a second electrical polarity. The first subset of vias and the second subset of vias may be in different metal layers of the silicon interposer circuit.

In the third embodiment, the method of making the optoelectronic device may also include forming at least one trench in the substrate, and connecting a third subset of resonant cavity mesas of the array of resonant cavity mesas to the silicon interposer substrate. The third subset of resonant cavity mesas may provide structural support for the first and second subsets of resonant cavity mesas. The at least one trench may electrically isolate the first subset of resonant cavity mesas from the second subset of resonant cavity mesas. The substrate may include at least one of gallium arsenide (GaAs), glass, or ceramic material. The optoelectronic device may include, or be packaged as, a system-in-package (SiP).

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIGS. 1A and 1B illustrate a portable electronic device, such as described herein.

FIG. 2 is an example electrical diagram of a number of resonant cavity devices, which resonant cavity devices may be provided in respective resonant cavity mesas of an optoelectronic device, such as described herein.

FIG. 3 illustrates a top view of a number of resonant cavity mesas on a substrate, such as described herein.

FIG. 4 illustrates a top view of a silicon interposer circuit, such as described herein.

FIG. 5 illustrates an elevation of a silicon interposer circuit, such as described herein.

FIGS. 6A-6C illustrate elevations of a number of resonant cavity mesas of an optoelectronic device, such as described herein.

FIG. 7 illustrates a method of making an optoelectronic device, such as described herein.

FIG. 8 is an electronic block diagram of an electronic device, such as described herein.

The use of the same or similar reference numerals in different figures indicates similar, related, or identical items.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments described herein relate to an optoelectronic device including one or more optical emitters or optical sensors. At least one optical emitter or optical sensor of the one or more optical emitters or optical sensors may include an array of resonant cavity mesas, which may be monolithically integrated in a set of one or more epitaxial layers on a substrate and bonded to a silicon interposer circuit in a flipped position. For example, a set of one or more epitaxial layers including the array of resonant cavity mesas may be flip-chip bonded to the silicon interposer circuit (which may be referred to herein as a silicon interposer). A subset of resonant cavity mesas of the array of the resonant cavity mesas may be operable as VCSEL diodes and/or a subset of resonant cavity mesas of the array of the resonant cavity mesas may be operable as resonant cavity photodetectors (RCPDs). The optoelectronic device, or each VCSEL diode or RCPD, may include an aperture to allow the light to be emitted and/or received (e.g., through reflection of the emitted light) by the optical emitter or optical sensor.

Although parts of the description provided herein are directed to providing ESD protection for VCSEL diodes, a person having ordinary skill in the art will understand that the described techniques are also applicable to providing ESD protection for RCPDs and other types of optoelectronic devices.

As described herein, and depending on the design of a particular optoelectronic device in which a VCSEL diode may be used, the VCSEL diode may be susceptible to ESD damage at different threshold voltages. Susceptibility of the VCSEL diode to ESD damage can vary in accordance with an aperture size used for the VCSEL diode. For example, at a very low aperture size, the VCSEL diode may experience ESD damage at a voltage level ranging from 40 to 50 volt (V), causing failure or decreased performance of an optical emitter or optical sensor including the VCSEL diode and/or causing failure or decreased performance of an optoelectronic device including the optical emitter or optical sensor. Conventionally, an optoelectronic device uses a separate module including transient voltage suppressor (TVS) diodes to protect a VCSEL diode from ESD damage. However, a module including TVS diodes tends to be bulky in weight, and its integration with other components of an optoelectronic device, including an optical emitter or optical sensor, may create additional integration problems and/or make the optoelectronic device bulky in weight and unsuitable for use in some optoelectronic devices and/or applications.

Accordingly, as described herein, and in accordance with some embodiments, protection against ESD damage may be provided by biasing a first subset of resonant cavity mesas in the array of resonant cavity mesas to a first electrical polarity, and biasing a second subset of resonant cavity mesas in the array of resonant cavity mesas to a second electrical polarity. By way of a non-limiting example, the first subset of resonant cavity mesas may be forward biased (or have a common anode junction area connected to a positive bias voltage, and a cathode connected to a negative bias voltage), and the second subset of resonant cavity mesas may be reverse biased (or have a common cathode junction area connected to the positive bias voltage, and an anode connected to the negative bias voltage). Further, each resonant cavity mesa of the first and second subsets of resonant cavity mesas may be integrated such that they are electrically connected in parallel. The first subset of resonant cavity mesas may be referred to herein as a main array of resonant cavity mesas, and the second subset of resonant cavity mesas may be referred to herein as an ESD protection array.

The reverse biased resonant cavity mesa(s) may provide protection from ESD damage for the forward biased resonant cavity mesa(s), as the reverse biased resonant cavity mesa(s), acting as diode, may become forward biased when there is a reverse voltage surge, thereby providing a pass-through for the ESD charge. Similarly, the forward biased resonant cavity mesa(s) may provide protection from ESD damage for the reverse biased resonant cavity mesa(s) under normal operating conditions and/or forward voltage surge conditions. Forward biased resonant cavity mesa(s) and reverse biased resonant cavity mesa(s) that are electrically connected in parallel may imitate a bidirectional TVS. Accordingly, a need for a separate module including TVS diodes may be avoided.

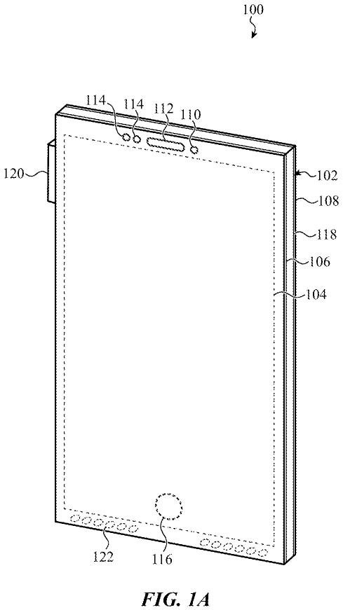

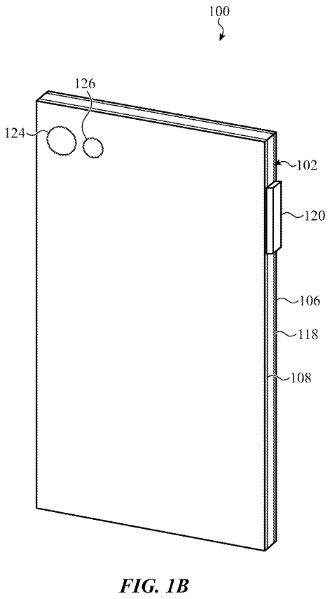

FIGS. 1A and 1B show a first example of a device 100 that may include an optoelectronic device. The device's dimensions and form factor, including the ratio of the length of its long sides to the length of its short sides, suggest that the device 100 is a mobile phone (e.g., a smartphone). However, the device's dimensions and form factor are arbitrarily chosen, and the device 100 could alternatively be any portable electronic device including, for example, a mobile phone, tablet computer, portable computer, portable music player, health monitor device, portable terminal, vehicle navigation system, robot navigation system, or other portable or mobile device. The device 100 could also be a device that is semi-permanently located (or installed) at a single location. FIG. 1A shows a front isometric view of the device 100, and FIG. 1B shows a rear isometric view of the device 100. The device 100 may include a housing 102 that at least partially surrounds a display 104. The housing 102 may include or support a front cover 106 or a rear cover 108. The front cover 106 may be positioned over the display 104, and may provide a window through which the display 104 may be viewed. In some embodiments, the display 104 may be attached to (or abut) the housing 102 and/or the front cover 106. In alternative embodiments of the device 100, the display 104 may not be included and/or the housing 102 may have an alternative configuration.

The display 104 may include one or more light-emitting elements including, for example, an LED, OLED, liquid crystal display (LCD), electroluminescent (EL) display, or other type of display element. In some embodiments, the display 104 may include, or be associated with, one or more touch and/or force sensors that are configured to detect a touch and/or a force applied to a surface of the front cover 106.

The various components of the housing 102 may be formed from the same or different materials. For example, the sidewall 118 may be formed using one or more metals (e.g., stainless steel), polymers (e.g., plastics), ceramics, or composites (e.g., carbon fiber). In some cases, the sidewall 118 may be a multi-segment sidewall including a set of antennas. The antennas may form structural components of the sidewall 118. The antennas may be structurally coupled (to one another or to other components) and electrically isolated (from each other or from other components) by one or more non-conductive segments of the sidewall 118. The front cover 106 may be formed, for example, using one or more of glass, a crystal (e.g., sapphire), or a transparent polymer (e.g., plastic) that enables a user to view the display 104 through the front cover 106. In some cases, a portion of the front cover 106 (e.g., a perimeter portion of the front cover 106) may be coated with an opaque ink to obscure components included within the housing 102. The rear cover 108 may be formed using the same material(s) that are used to form the sidewall 118 or the front cover 106. In some cases, the rear cover 108 may be part of a monolithic element that also forms the sidewall 118 (or in cases where the sidewall 118 is a multi-segment sidewall, those portions of the sidewall 118 that are non-conductive). In still other embodiments, all of the exterior components of the housing 102 may be formed from a transparent material, and components within the device 100 may or may not be obscured by an opaque ink or opaque structure within the housing 102.

The front cover 106 may be mounted to the sidewall 118 to cover an opening defined by the sidewall 118 (i.e., an opening into an interior volume in which various electronic components of the device 100, including the display 104, may be positioned). The front cover 106 may be mounted to the sidewall 118 using fasteners, adhesives, seals, gaskets, or other components.

A display stack or device stack (hereafter referred to as a “stack”) including the display 104 may be attached (or abutted) to an interior surface of the front cover 106 and extend into the interior volume of the device 100. In some cases, the stack may include a touch sensor (e.g., a grid of capacitive, resistive, strain-based, ultrasonic, or other type of touch sensing elements), or other layers of optical, mechanical, electrical, or other types of components. In some cases, the touch sensor (or part of a touch sensor system) may be configured to detect a touch applied to an outer surface of the front cover 106 (e.g., to a display surface of the device 100).

In some cases, a force sensor (or part of a force sensor system) may be positioned within the interior volume below and/or to the side of the display 104 (and in some cases within the device stack). The force sensor (or force sensor system) may be triggered in response to the touch sensor detecting one or more touches on the front cover 106 (or a location or locations of one or more touches on the front cover 106), and may determine an amount of force associated with each touch, or an amount of force associated with the collection of touches as a whole.

As shown primarily in FIG. 1A, the device 100 may include various other components. For example, the front of the device 100 may include one or more front-facing cameras 110, speakers 112, microphones, or other user-facing sensors 114 (e.g., an optical proximity sensor as described in various embodiments herein). In some embodiments, the user-facing sensors 114 may include an optical sensor having an optical emitter and light emission path and/or an optical sensor and light reception path, such as described herein. In some cases, a front-facing camera 110, alone or in combination with other sensors, may be configured to operate as a bio-authentication or facial recognition sensor. The device 100 may also include various input devices, including a mechanical or virtual button 116, which may be accessible from the front surface (or display surface) of the device 100. In some cases, the front-facing camera 110, virtual button 116, and/or other sensors of the device 100 may be integrated with a display stack of the display 104 and moved under the display 104.

The device 100 may also include buttons or other input devices positioned along the sidewall 118 and/or on a rear surface of the device 100. For example, a volume button or multipurpose button 120 may be positioned along the sidewall 118, and in some cases may extend through an aperture in the sidewall 118. The sidewall 118 may include one or more ports 122 that allow air, but not liquids, to flow into and out of the device 100. In some embodiments, one or more sensors may be positioned in or near the port(s) 122. For example, an ambient pressure sensor, ambient temperature sensor, internal/external differential pressure sensor, gas sensor, particulate matter sensor, or air quality sensor may be positioned in or near a port 122.

In some embodiments, the rear surface of the device 100 may include a rear-facing camera 124 or other optical sensor (see FIG. 1B). A flash or light source 126 may also be positioned along the rear of the device 100 (e.g., near the rear-facing camera). In some cases, the rear surface of the device 100 may include multiple rear-facing cameras.

As discussed above, it may be desirable to maximize the portion of the device 100 dedicated to the display 104 while minimizing the portion of the device 100 dedicated to the other user facing sensors 114.

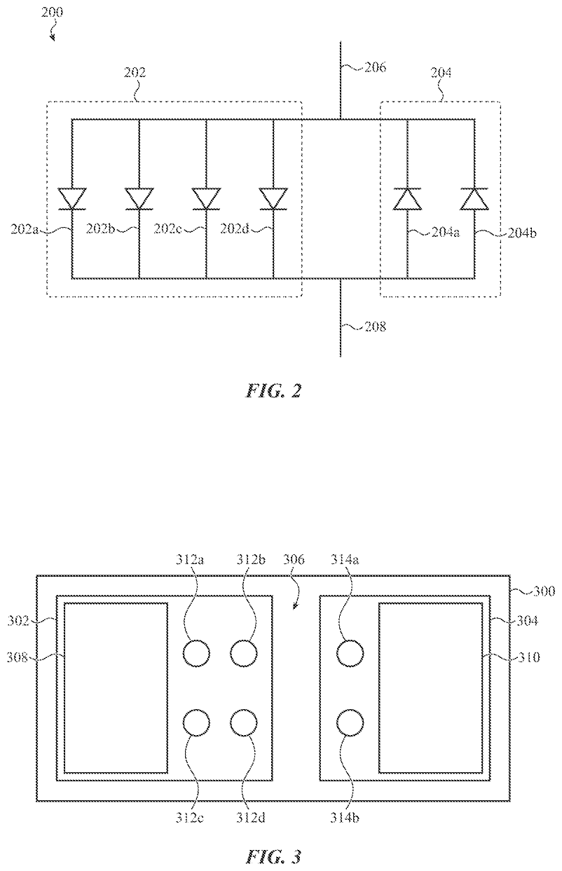

FIG. 2 is an example electrical diagram of a number of resonant cavity devices, which resonant cavity devices may be provided in respective resonant cavity mesas of an optoelectronic device, such as described herein. As shown in FIG. 2, an electrical diagram 200 may represent a number of resonant cavity devices of an optical emitter. As described herein, the number of resonant cavity devices may be generally constructed as VCSEL diodes, which are represented in FIG. 2 as 202a-202d. The VCSEL diodes 202a-202d may be biased to a first electrical polarity (e.g., with their anodes connected to a positive bias voltage 206 and their cathodes connected to ground or a negative bias voltage 208, or with their anodes connected to a higher voltage than their cathodes), and the diodes 204a-204b may be biased to a second electrical polarity (e.g., with their cathodes connected to the positive bias voltage 206 and their anodes connected ground or a negative bias voltage 208, or with their cathodes connected to a higher voltage than their anodes). The VCSEL diodes 202a-202d may belong to a first group 202, e.g., a main array 202 of VCSEL diodes, and the diodes 204a-204b may belong to a second group 204, e.g., an ESD protection array 204 of diodes (i.e., diodes that do not lase and which are configured to provide ESD protection to the VCSEL diodes of the first group 202).

As described herein, the main array 202 of VCSEL diodes may be an array of forward biased VCSEL diodes, and the ESD protection array 204 of diodes may be an array of reverse biased diodes. The reverse biased diodes of the ESD protection array protect the forward biased VCSEL diodes of the main array from being damaged in case there is a return voltage surge, as the reverse biased diodes become forward biased when there is a surge in reverse voltage, allowing a charge (e.g., an ESD) to pass through. Similarly, the forward biased VCSEL diodes of the main array protect the reverse biased diodes of the ESD protection array from being damaged in normal operating conditions and/or a forward voltage surge condition, as the forward biased VCSEL diodes become reverse biased when there is a surge in forward voltage and allowing a charge (e.g., an ESD) to pass through. Accordingly, the forward biased VCSEL diodes and the reverse biased diodes, connected in parallel as shown in FIG. 2, imitate a bidirectional TVS and provide protection against ESD damage.

FIG. 3 illustrates a top view 300 of a number of resonant cavity mesas on a substrate, such as described herein. As shown in the view 300, a set of forward biased resonant cavity mesas 302 and a set of reverse biased resonant cavity mesas 304 are electrically isolated from each other by a deep trench 306. The set of forward biased resonant cavity mesas 302 and the set of reverse biased resonant cavity mesas 304 may correspond to the main array 202 and the ESD protection array 204, respectively, and accordingly form a bidirectional TVS, which provides protection against damage from ESD, as described herein with reference to FIG. 2.

As shown in FIG. 3, the set of forward biased resonant cavity mesas 302 may include a number of resonant cavity mesas 312a-312d that are electrically connected to a common anode junction area 308, and the set of reverse biased resonant cavity mesas 304 may include a number of resonant cavity mesas 314a-314b that are electrically connected to a common cathode junction area 310.

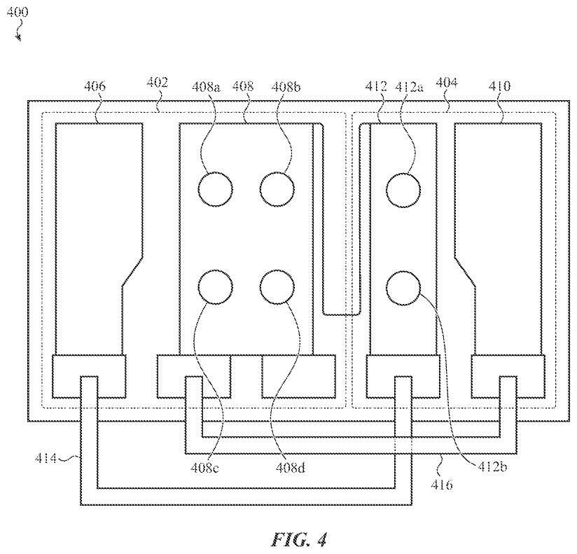

FIG. 4 illustrates a top view of a silicon interposer circuit, such as described herein. In particular, the view 400 of the silicon interposer circuit shows a first set of resonant cavity mesas 402, including resonant cavity mesas 408a-408d, biased to a first electrical polarity. View 400 also shows a second set of resonant cavity mesas 404, including resonant cavity mesas 412a-412b, biased to a second electrical polarity. As shown in view 400, the first set of resonant cavity mesas 402 may be electrically connected to a common anode junction area 406, and the second set of resonant cavity mesas 404 may be electrically connected to a common cathode junction area 410. Further, the common anode junction area 406, and the resonant cavity mesas 412a-412b may be biased to the first electrical polarity using a routing or a via 414 connected to, for example, a positive bias supply voltage source (not shown), and the common cathode junction area 410, and the resonant cavity mesas 408a-408d may be biased to the second electrical polarity using a routing or a via 416 connected to, for example, a negative bias supply voltage source (not shown). In addition, the resonant cavity mesas 408a-408d of the first set of resonant cavity mesas 402, and the resonant cavity mesas 412a-412b of the second set of resonant cavity mesas 404 may also be connected to a ground (GND) using a routing or a via (not shown). The routing or the via 414, the routing or the via 416, and/or the routing or the via for the GND may be in different metal layers of a silicon interposer circuit. Accordingly, the silicon interposer circuit may have at least two conductive (e.g., metal) layers.

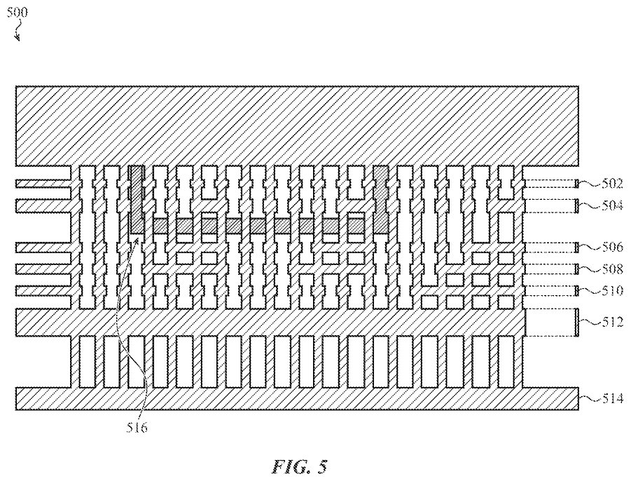

FIG. 5 illustrates an elevation of a silicon interposer circuit, such as described herein. As shown in a vertical cross-section view 500 of a silicon interposer circuit, the silicon interposer circuit may have a number of metal layers. By way of example, a silicon interposer circuit including seven different metal layers 502, 504, 506, 508, 510, 512, and 514 is shown in FIG. 5. The number of metal layers of the silicon interposer circuit and a particular thickness and/or a width of each metal layer may vary in accordance with a size of a node, for example. A routing or a via may be formed in one or more metal layers of the silicon interposer circuit, and an example routing or via 516 shown in FIG. 5 may be an example of the routing or the via 414 or 416. The silicon interposer circuit may be made of silicon material, but other materials, such as glass, ceramic, and so on, may also be used for an interposer circuit.

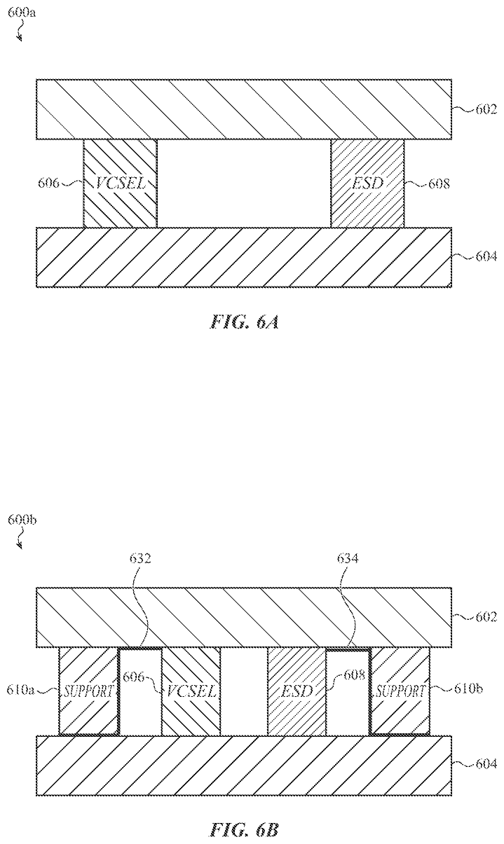

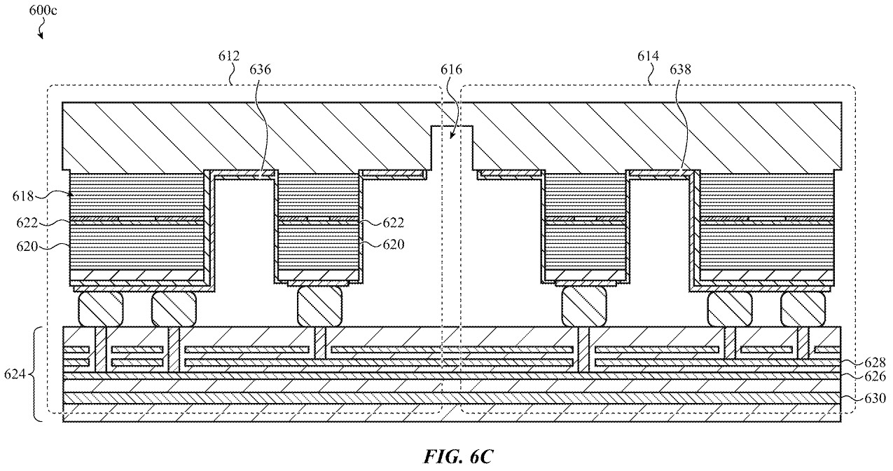

FIGS. 6A-6C illustrate elevations of a number of resonant cavity mesas of an optoelectronic device, such as described herein. As shown in view 600a of FIG. 6A, a first resonant cavity mesa 606 and a second resonant cavity mesa 608 are disposed between two layers 602 and 604. The first layer 602 may be a common substrate and the second layer 604 may be an interposer circuit. Alternatively, the first layer 602 may be an interposer circuit and the second layer 604 may be a common substrate. The first resonant cavity mesa 606 may be a VCSEL diode, and in some cases may be a VCSEL in an array of VCSELs, as described herein. The resonant cavity mesa 608 may be a diode of the ESD protection array, as described herein. A view 600b of FIG. 6B further shows mesas 610a and 610b, which may provide mechanical or structural support to the resonant cavity mesas 606 and 608. In some embodiments, all of the mesas 606, 608, 610a, 610b may be constructed in parallel, using the same process, as resonant cavity mesas, but only some of the mesas (e.g., mesa 606) may be biased as resonant cavity mesas and have functional resonant cavities. Other mesas (e.g., mesa 608) may be electrically biased and operated as diodes. Other mesas (e.g., mesas 610a and 610b) may not have an operable resonant cavity. Some of the mesas with inoperable resonant cavities (e.g., mesas 610a and 610b) may, however, be used to support elements that form part or all of an anode 632, cathode 634, or other conductive element (e.g., a conductive route to/from an interposer circuit), as described in more detail with reference to FIG. 6C. The common substrate may be made of gallium arsenide (GaAs), glass, and/or ceramic, or other similar material. The interposer circuit may be made of silicon, glass, and/or ceramic, or other similar material.

A view 600c of FIG. 6C illustrates the substrate, the interposer circuit, the VCSEL diode (e.g., a VCSEL diode in an array of VCSEL diodes) and the diode of the ESD protection array, and mesas providing mechanical or structural support and/or conductive routing, in more detail. As shown in the view 600c, the main array 612 may include a first number of resonant cavity mesas, and the ESD protection array 614 may include a second number of resonant cavity mesas. The first number of resonant cavity mesas of the main array 612 may be electrically isolated from the second number of resonant cavity mesas of the ESD protection array 614 by a deep trench (or an isolation trench) 616. The deep trench 616 may be formed of, or filled, using a doping material that is not electrically conductive, to provide isolation between a resonant cavity mesa of the main array 612 and a resonant cavity mesa of the ESD protection array 614. Further, one or more mesas, shown in FIG. 6C as 618, may be formed to provide mechanical or structural support to the first number of resonant cavity mesas of the main array 612 and/or the second number of resonant cavity mesa of the ESD protection array 614. The mesas 618 may also provide surfaces on which an anode 636 or cathode 638 can be routed, for purposes of biasing the VCSEL diode of the main array 612 or the diode of the ESD protection array 614.

As shown in the view 600c, an interposer circuit 624, such as the interposer circuit described herein with reference to FIG. 5, may include a number of metal layers and a number of dielectric layers. For example, the interposer circuit 624 may include at least a first layer 626, a second layer 628, and a third layer 630, and so on. The first layer 626 may connect anodes of the first number of resonant cavity mesas and the second number of resonant cavity mesas of the main array and the ESD protection array, respectively, and the second layer 628 may connect cathodes of the first number of resonant cavity mesas and the second number of resonant cavity mesas of the main array and the ESD protection array, respectively. The third layer 630 may provide a Ground (GND) return path. In the view 600c, 620 represents distributed Bragg reflectors (DBRs) and 622 represents quantum wells (QWs) in the resonant cavity mesas. Since various techniques for constructing DBRs and QWs are well-known to a person skilled in the art, details of the DBRs and/or QWs are not described herein.

In particular, the view 600c shows resonant cavity mesas configured or formed as back-side emission VCSEL diodes, or diodes, and having a deep trench between the forward biased main array and the reverse biased ESD protection array. The common substrate may be of semi-insulating material. Additionally, or alternatively, an n-type substrate with an electrical current isolating layer between the n-type substrate and one or more epitaxial layers of the substrate may be used.

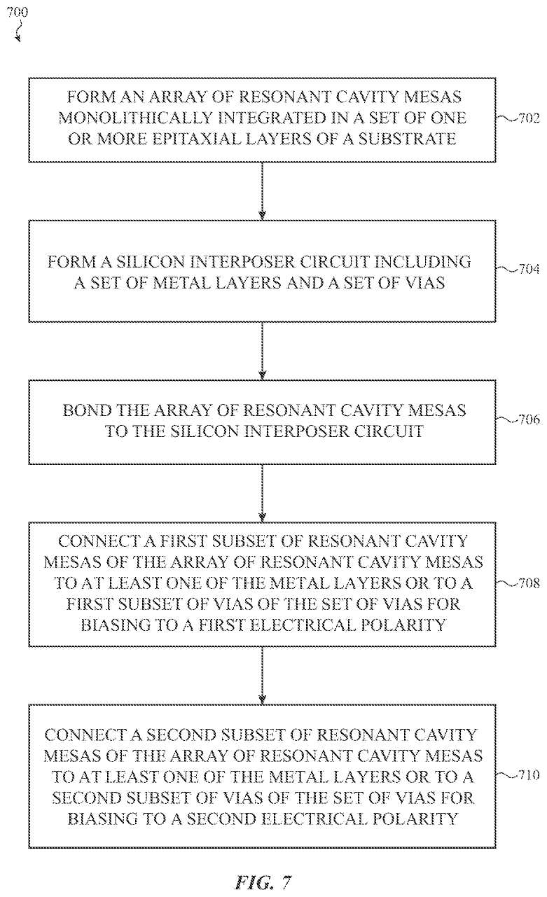

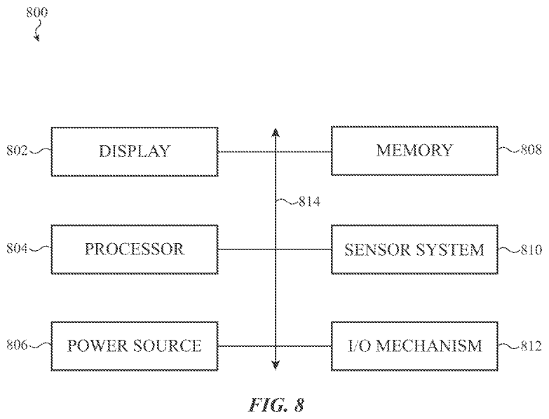

FIG. 7 illustrates a method of making an optoelectronic device, such as described herein. As shown at 702, an array of resonant cavity mesas, monolithically integrated in a set of one or more epitaxial layers, may be formed on a substate. The array of resonant cavity mesas may be formed on a single substrate of, for example, GaAs, glass, and/or ceramic material. Since techniques to form a resonant cavity mesa in one or more epitaxial layers on a substrate is known, those details are not described herein.

At 704, a silicon interposer circuit including a set of metal layers and a set of vias may be formed. As described herein, the set of metal layers may include at least two metal layers, and by way of a non-limiting example, the set of metal layers may include seven metal layers. The set of vias may connect the resonant cavity mesas to a positive bias voltage supply, a negative bias voltage supply, and/or a GND return path. The set of vias may include a first subset of vias in a first metal layer and a second subset of vias in a second metal layer. By way of a non-limiting example, a particular via may be disposed in more than one metal layer. The interposer circuit may be formed of, for example, silicon, glass, and/or ceramic material.

At 706, the array of resonant cavity mesas may be bonded to the silicon interposer circuit formed at 704, In particular, the bonding of the array of resonant cavity mesas and the silicon interposer may be achieved by connecting a first subset of resonant cavity mesas of the array of resonant cavity mesas to at least a first metal layer of the metal layers or to a first subset of vias of the set of vias at 708. Further, the first subset of resonant cavity mesas of the array of resonant cavity mesas may be electrically connected or coupled to a first electrical polarity for biasing the first subset of resonant cavity mesas of the array of resonant cavity mesas.

Further, the bonding of the array of resonant cavity mesas and the silicon interposer may be achieved by connecting a second subset of resonant cavity mesas of the array of resonant cavity mesas to at least a second metal layer of the metal layers or to a second subset of vias of the set of vias at 710. Further, the second subset of resonant cavity mesas of the array of resonant cavity mesas may be electrically connected or coupled to a second electrical polarity for biasing the second subset of resonant cavity mesas of the array of resonant cavity mesas. As described herein, the first subset of resonant cavity mesas of the array of resonant cavity mesas and the second subset of resonant cavity mesas of the array of resonant cavity mesas may be forward biased and reverse biased, respectively, and forming a bidirectional TVS providing protection against damage from ESD to each resonant cavity mesa of an optical sensor.

An optoelectronic device made using the operations described above with reference to FIG. 7 may include a system-in-package (SiP) or may be packaged in a SiP. Further, a number of resonant cavity mesas in the first subset and the second subset of resonant cavity mesas may not be the same. In other words, a number of resonant cavity mesas in the first subset (or a main array) of the resonant cavity mesas may be more than a number of resonant cavity mesas in the second subset (or an ESD protection array) of the resonant cavity mesas. In other words, a ratio of a number of forward biased resonant cavity mesas to a number of reverse biased resonant cavity mesas may be n:1 or 1:n, where n is not equal to 1. Alternatively, n may be equal to 1.

FIG. 8 shows a sample electrical block diagram of an electronic device 800, which may in some cases take the form of the device described with reference to FIGS. 1A-1B and/or include an optoelectronic device, such as a front-facing camera, proximity sensor, ambient light sensor, fingerprint reader, depth-sensing camera, or the like having a number of resonant cavity mesas, as described with reference to any of FIGS. 2-7. The electronic device 800 may include a display 802 (e.g., a light-emitting display), a processor 804, a power source 806, a memory 808 or storage device, a sensor system 810, or an input/output (I/O) mechanism 812 (e.g., an input/output device, input/output port, or haptic input/output interface). The processor 804 may control some or all of the operations of the electronic device 800. The processor 804 may communicate, either directly or indirectly, with some or all of the other components of the electronic device 800. For example, a system bus or other communication mechanism 814 can provide communication between the display 802, the processor 804, the power source 806, the memory 808, the sensor system 810, and the I/O mechanism 812.

The processor 804 may be implemented as any electronic device capable of processing, receiving, or transmitting data or instructions, whether such data or instructions is in the form of software or firmware or otherwise encoded. For example, the processor 804 may include a microprocessor, a central processing unit (CPU), an application-specific integrated circuit (ASIC), a digital signal processor (DSP), a controller, or a combination of such devices. As described herein, the term “processor” is meant to encompass a single processor or processing unit, multiple processors, multiple processing units, or other suitably configured computing element or elements.

It should be noted that the components of the electronic device 800 can be controlled by multiple processors. For example, select components of the electronic device 800 (e.g., the sensor system 810) may be controlled by a first processor and other components of the electronic device 800 (e.g., the display 802) may be controlled by a second processor, where the first and second processors may or may not be in communication with each other.

The power source 806 can be implemented with any device capable of providing energy to the electronic device 800. For example, the power source 806 may include one or more batteries or rechargeable batteries. Additionally, or alternatively, the power source 806 may include a power connector or power cord that connects the electronic device 800 to another power source, such as a wall outlet.

The memory 808 may store electronic data that can be used by the electronic device 800. For example, the memory 808 may store electrical data or content such as, for example, audio and video files, documents and applications, device settings and user preferences, timing signals, control signals, and data structures or databases. The memory 808 may include any type of memory. By way of example only, the memory 808 may include random access memory, read-only memory, Flash memory, removable memory, other types of storage elements, or combinations of such memory types.

The electronic device 800 may also include one or more sensor systems 810 positioned almost anywhere on the electronic device 800. In some cases, sensor systems 810 may be positioned as described with reference to FIGS. 1A-1B. The sensor system(s) 810 may be configured to sense one or more type of parameters, such as but not limited to, light; touch; force; heat; movement; relative motion; biometric data (e.g., biological parameters) of a user; particulate matter concentration; air quality; proximity; position; connectedness; and so on. By way of example, the sensor system(s) 810 may include a temperature sensor, a position sensor, a light or optical sensor, an accelerometer, a pressure transducer, a gyroscope, a magnetometer, a health monitoring sensor, a particulate matter sensor, an air quality sensor, and so on. Additionally, the one or more sensor systems 810 may utilize any suitable sensing technology, including, but not limited to, magnetic, capacitive, ultrasonic, resistive, optical, acoustic, piezoelectric, or thermal technologies.

The I/O mechanism 812 may transmit or receive data from a user or another electronic device. The I/O mechanism 812 may include the display 802, a touch sensing input surface, a crown, one or more buttons (e.g., a graphical user interface “home” button), one or more cameras (including an under-display camera), one or more microphones or speakers, one or more ports such as a microphone port, and/or a keyboard. Additionally, or alternatively, the I/O mechanism 812 may transmit electronic signals via a communications interface, such as a wireless, wired, and/or optical communications interface. Examples of wireless and wired communications interfaces include, but are not limited to, cellular and Wi-Fi communications interfaces.

It is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

As used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

Although the disclosure above is described in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the some embodiments of the invention, whether or not such embodiments are described and whether or not such features are presented as being a part of a described embodiment. Thus, the breadth and scope of the present invention should not be limited by any of the above-described exemplary embodiments but is instead defined by the claims herein presented.

As described herein, the term “processor” refers to any software and/or hardware-implemented data processing device or circuit physically and/or structurally configured to instantiate one or more classes or objects that are purpose-configured to perform specific transformations of data including operations represented as code and/or instructions included in a program that can be stored within, and accessed from, a memory. This term is meant to encompass a single processor or processing unit, multiple processors, multiple processing units, analog or digital circuits, or other suitably configured computing element or combination of elements.

What is claimed is:

1. An optoelectronic device, comprising:
a silicon interposer;
an array of resonant cavity mesas monolithically integrated in a set of one or more epitaxial layers and flip-chip bonded to the silicon interposer, the array of resonant cavity mesas including,
a first subset of resonant cavity mesas connected to a first subset of conductors of the silicon interposer and biased to a first electrical polarity; and
a second subset of resonant cavity mesas connected to a second subset of conductors of the silicon interposer, the second subset of resonant cavity mesas providing electrostatic discharge (ESD) protection for the first subset of resonant cavity mesas.

2. The optoelectronic device of claim 1, wherein:
the first subset of resonant cavity mesas is forward biased and operable as a set of vertical cavity surface-emitting laser (VCSEL) diodes; and
the second subset of resonant cavity mesas is reverse biased.

3. The optoelectronic device of claim 1, wherein:
the first subset of resonant cavity mesas is reverse biased and operable as a set of resonant cavity photodetectors (RCPDs); and
the second subset of resonant cavity mesas is forward biased.

4. The optoelectronic device of claim 1, wherein the silicon interposer has n>2 metal layers.

5. The optoelectronic device of claim 1, wherein:
the silicon interposer includes a set of metal layers;
the first subset of conductors includes conductors disposed in at least a first metal layer of the set of metal layers; and
the second subset of conductors includes conductors disposed in at least a second metal layer of the set of metal layers, the second metal layer different from the first metal layer.

6. The optoelectronic device of claim 1, wherein a ratio of a first number of resonant cavity mesas in the first subset of resonant cavity mesas to a second number of resonant cavity mesas in the second subset of resonant cavity mesas is other than 1:1.

7. The optoelectronic device of claim 1, wherein the array of resonant cavity mesas further includes a third subset of resonant cavity mesas connected to the silicon interposer and providing structural support for the first and second subsets of resonant cavity mesas.

8. An optoelectronic device, comprising:
an array of resonant cavity mesas formed on a common substrate and including a first subset of resonant cavity mesas and a second subset of resonant cavity mesas; wherein,
a first two or more resonant cavity mesas of the first subset of resonant cavity mesas are electrically biased to a first polarity and are operable as vertical cavity surface-emitting laser (VCSEL) diodes; and
a second two or more resonant cavity mesas of the second subset of resonant cavity mesas are electrically biased to a second polarity and provide electrostatic discharge (ESD) protection for the first two or more resonant cavity mesas; and
at least one trench in the common substrate electrically isolating the first subset of resonant cavity mesas from the second subset of resonant cavity mesas.

9. The optoelectronic device of claim 8, further comprising a silicon interposer, the array of resonant cavity mesas attached to the silicon interposer with the array of resonant cavity mesas disposed between the common substrate and the silicon interposer.

10. The optoelectronic device of claim 9, wherein:
the first two or more resonant cavity mesas of the first subset of resonant cavity mesas are electrically biased to the first polarity using a first subset of conductors disposed in the silicon interposer; and
the second two or more resonant cavity mesas of the second subset of resonant cavity mesas are electrically biased to the second polarity using a second subset of conductors disposed in the silicon interposer.

11. The optoelectronic device of claim 10, wherein the first subset of conductors is disposed in at least a first metal layer of the silicon interposer that is different from at least a second metal layer of the silicon interposer in which the second subset of conductors is disposed.

12. The optoelectronic device of claim 8, wherein a ratio of a number of resonant cavity mesas of the first subset of resonant cavity mesas to a number of resonant cavity mesas of the second subset of resonant cavity mesas is n:1, and n is not equal to 1.

13. The optoelectronic device of claim 8, wherein a ratio of a number of resonant cavity mesas of the first subset of resonant cavity mesas to a number of resonant cavity mesas of the second subset of resonant cavity mesas is 1:n, and n is not equal to 1.

14. The optoelectronic device of claim 8, wherein the first subset of resonant cavity mesas and the second subset of resonant cavity mesas form a set of forward biased diodes and a set of reverse biased diodes, respectively, connected in parallel and providing a bidirectional transient voltage suppressor (TVS).

15. A method of making an optoelectronic device, the method comprising:
forming an array of resonant cavity mesas monolithically integrated in a set of one or more epitaxial layers on a substrate;
forming a silicon interposer circuit including a set of metal layers and a set of vias; and
bonding the array of resonant cavity mesas to the silicon interposer circuit, the bonding,
connecting a first subset of resonant cavity mesas of the array of resonant cavity mesas to at least a first metal layer of the set of metal layers or to a first subset of vias of the set of vias, the connecting biasing the first subset of resonant cavity mesas to a first electrical polarity; and
connecting a second subset of resonant cavity mesas of the array of resonant cavity mesas to at least a second metal layer of the set of metal layers or to a second subset of vias of the set of vias, the connecting biasing the second subset of resonant cavity mesas to a second electrical polarity.

16. The method of claim 15, wherein the optoelectronic device comprises a system-in-package (SiP).

17. The method of claim 15, further comprising forming at least one trench in the substrate, the at least one trench electrically isolating the first subset of resonant cavity mesas from the second subset of resonant cavity mesas.

18. The method of claim 15, further comprising connecting a third subset of resonant cavity mesas of the array of resonant cavity mesas to a silicon interposer substrate, the third subset of resonant cavity mesas providing structural support for the first and second subsets of resonant cavity mesas.

19. The method of claim 15, wherein the substrate comprises at least one of gallium arsenide, glass, or ceramic.

20. The method of claim 15, wherein the first subset of vias connects to the first metal layer of the set of metal layers and the second subset of vias connects to the second metal layer of the set of metal layers.
